(19) United States
(12) Patent Application Publication
(10) Pub. No.: US 2019/0221443 A1
(43) Pub. Date: Jul. 18, 2019

(54) CONDUCTING WIRE PROCESS ARRAY ETCHING METHOD

(71) Applicants: HKC Corporation Limited, Shenzhen (CN); Chongqing HKC Optoelectronics Technology Co., Ltd., Chongqing (CN)

(72) Inventor: YU-JEN CHEN, Chongqing (CN)

(21) Appl. No.: 16/325,747

(22) PCT Filed: May 5, 2017
(86) PCT No.: PCT/CN2017/083214

§ 371 Date: Feb. 15, 2019

(30) Foreign Application Priority Data
Dec. 30, 2016 (CN) 201611257736.2

(51) Int. Cl. H01L 21/3213; H01L 21/306; H01L 27/12; H01L 29/40; H01L 29/66; G02F 1/1368; H01L 29/417; H01L 29/45; H01L 21/02; H01L 21/027

(52) U.S. Cl. CPC H01L 21/32134; H01L 21/30604; H01L 27/1288; H01L 29/401; H01L 21/0273; G02F 1/1368; H01L 29/41733; H01L 29/45; H01L 21/02068; H01L 29/66742

(57) ABSTRACT

The present application discloses a conducting wire process array etching method. The method includes the steps of etching a multilayer metal film with metal etching liquid, removing, residual metal, and etching a semiconductor layer.

TECHNICAL FIELD

The present application relates to the technical field of displays, and in particular relates to a conducting wire process array etching method.

### BACKGROUND

Microcircuits of a semiconductor apparatus and a liquid crystal display apparatus are formed through a series of photoetching processes, where photoresist is uniformly coated onto aluminum, aluminum alloys, copper, copper alloys, or other conductive metal films. Alternatively, the photoresist may be coated on silicon dioxide film, silicon nitride film, or other insulating films formed on a substrate. The photoetching process also includes performing light irradiation on the film with patterns, imaging needed patterns on the photoresist, using a dry-type etching or a wet-type etching method to display patterns on the metal film or the insulating film at a lower portion of the photoresist, and stripping and removing undesirable photoresist.

Metal and particularly copper alloys used in a source/drain has a low impedance and is environmentally friendly compared to using an aluminum-chrome wire in the prior art. However, use of novel metal also has some problems. For example, copper has the problem of low adhesion to a glass substrate and the insulating film, and its easiness to diffuse into silicon oxide film, etc. Because of this, titanium, molybdenum, and the like, are generally used as a lower film metal to form a multilayer metal film.

After the multilayer metal film is used, manufacturing of a thin film transistor has low yield problems, bringing about trouble to those of skill in the art.

It shall be noted that the introduction about the background is intended to clearly and completely describe technical solutions of the present application, and to facilitate the understanding of those of skill in the art. The description of the solutions at the background of the present application shall not be considered as that the above technical solutions are well-known to those of skill in the art.

### SUMMARY

In view of the defects of the prior art, the technical problem to be solved by the present application is to provide a conducting wire process array etching method capable of ensuring a product yield.

In order to realize the above aim, the present application provides a conducting wire process array etching method, including the following steps:

etching a multilayer metal film with metal etching liquid;

removing residual metal; and

etching a semiconductor layer.

Optionally, prior to the etching of the semiconductor layer, the method further includes the step:

removing a photoresist.

Optionally, the residual metal is residual molybdenum, and

the photoresist and the residual molybdenum simultaneously removed using universal stripping, liquid. In the present solution, the multilayer metal film includes a copper/molybdenum multilayer film or an aluminum/molybdenum multilayer film. When the metal etching liquid is used for etching, because the metal etching liquid has a bad effect on etching the molybdenum, when a critical dimension (CD) bias requirement is met after the etching of the copper/aluminum is completed, etching of the molybdenum is not completed yet, thus causing the molybdenum to remain. At the moment, a universal stripping liquid is used to remove the residual molybdenum and the glass photoresist, so that the N+ residue can be avoided when in N+ etching, and the product yield can be ensured.

Further, the universal stripping liquid includes a high-concentration of amine stripping liquid. A main component of the universal stripping liquid is a high-concentration of amine stripping liquid, and using the universal stripping liquid can simultaneously complete the removal of the residual molybdenum and the photoresist, thereby achieving dual purposes.

Optionally, the photoresist is removed by adopting a copper stripping liquid.

Optionally, after the step of etching the semiconductor layer, the method further includes the step:

removing a photoresist using the copper stripping liquid. The photoresist is removed after the N+ etching is removed, so that a situation where other portions of the multilayer metal film are carelessly etched when performing N+ etching or removing the residual molybdenum, can be avoided.

Optionally, the multilayer metal film is a copper/molybdenum multilayer film.

The metal etching liquid includes the copper etching liquid. The copper etching liquid mainly includes S/D cupric acid, and is mainly used for etching copper or copper alloys. Meanwhile, the copper etching liquid also has an effect on etching the metal at a lower layer such as the molybdenum. Of course, under an allowable condition, the copper etching liquid can also be mixed acid based on hydrogen peroxide or mixed acid based on phosphoric acid, etc., which is not repeated herein as being not a main inventive point of the present application.

Optionally, the copper/molybdenum multilayer film includes a multilayer film having a copper upper layer and a lower molybdenum layer, or the multilayer film having a copper middle layer and upper and lower layers of molybdenum. Because the copper has low adhesion to the glass substrate and an insulating film, and the silicon oxide film has a problem of easiness in diffusion, the bad adhesion to the semiconductor layer herein may lead to unnecessary problems, so that the copper multilayer film is replaced by the multilayer film having a copper upper layer and a lower molybdenum layer, or the multilayer film having a copper middle layer and upper and lower layers of molybdenum.

Optionally, the multilayer metal film is the copper/molybdenum multilayer film, and the copper/molybdenum multilayer includes a multilayer film having a copper upper layer and a lower molybdenum layer, or the multilayer film having a copper middle layer and upper and lower layers of molybdenum.

While the residual molybdenum is removed, the photoresist is also removed,

The photoresist and the residual molybdenum are removed using the high-concentration amine stripping liquid.

Optionally, prior to the step of etching the multilayer metal film with the metal etching liquid, the method further includes the steps:

forming a gate on a substrate;

forming a gate insulation layer on the substrate including the gate;

forming a semiconductor layer on the gate insulation layer;

forming a source and a drain on the semiconductor layer; and

forming a pixel electrode connected with the drain.

As being unrelated to the inventive point of the present application, an exposure and development step is not shown herein, where the source and the drain are formed by the multilayer metal film. In the present solution, because a preliminary process is not a main inventive point of the present application, the involved manufacturing process of the gate/source/drain prior to the etching process is not repeated herein.

The present application has the beneficial effects, in using the multilayer metal film, when patterns are etched, incomplete etching is easy to occur, and resulting in N+ residue in subsequent etching of the semiconductor, leading to low product yield and high production cost. In the present application, because the residual metal is actually removed after the metal etching liquid is used to etch the multilayer metal film, so that the problem of the N+ residue in subsequent processes is avoided, product yield is increased, and production cost is reduced. Specifically, the multilayer metal film may be a copper/molybdenum multilayer film, an aluminum/molybdenum multilayer film, a copper/titanium multilayer film, and the like, the corresponding metal etching liquid is mainly used for etching copper or aluminum, and also is used for certain etching purposes for the molybdenum and titanium, but the problem of slow etching of the metal on a lower portion is likely to occur to cause the problem of the residual metal at the lower portion, and the residual metal problem will lead to the incomplete etching of N+ in subsequent. N+ etching process. In consideration of this problem, and particularly for the problem of the residual metal at the lower portion of the multilayer metal film selected by the inventor, the specific removal of the residual metal is performed, so that when the N+ etching is performed, the problem of incomplete etching of N+ caused by the residual metal at the upper portion of the N+ semiconductor layer is avoided, and product yield is ensured. The etching liquid used for the N+ etching can be selected from a conventional etching liquid as long as the etching liquid meets N+ etching requirements.

Referring to the descriptions and drawings below, specific embodiments of the present application are disclosed in detail, and a way that may be employed by a principle of the present application is pointed out. It shall be appreciated that the scope of embodiments of the present application is not limited. Embodiments of the present application include various changes, modifications and equivalents within the spirit and term of the attached claims.

Descriptions and/or shown features of one embodiment can be used in one or more other embodiments in a same or similar way and can be combined with the features in other embodiments or can substitute the features in other embodiments.

It shall be emphasized that the term “comprising/including” used herein refers to the presence of features, parts, steps or components, but the presence or addition of one or more other features, parts, steps or components is not excluded.

### BRIEF DESCRIPTION OF THE DRAWINGS

The included drawings are used to provide further understanding of embodiments of the present application, constitute a portion of the description, and are used to illustrate embodiments of the present application and to describe the principle of the present application together with words. Apparently, the drawings in the following description are only some embodiments of the present application, and those of ordinary skill in the art can obtain other drawings on the premise of not contributing innovative work. In the drawings:

FIG. 1 is a flowchart of a process for manufacturing a thin film transistor substrate used by the present application;

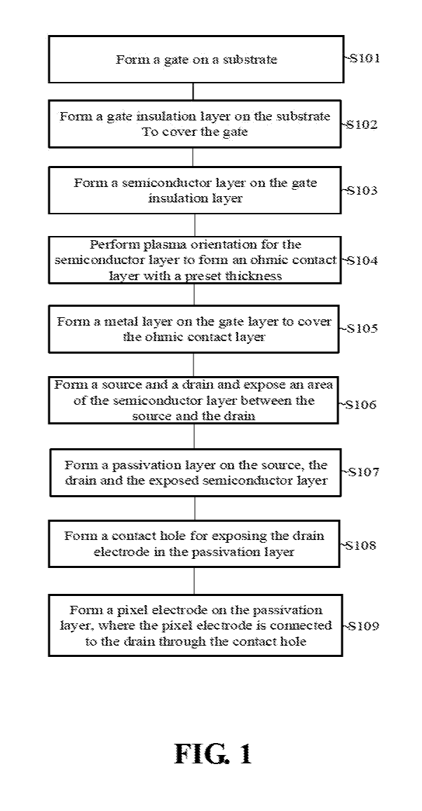

FIG. 2 is a flowchart of a conducting wire process array etching method before an improvement of the present application;

FIG. 3 is a flowchart of a conducting wire process array etching method of the present application;

FIG. 4 is a flowchart of another conducting wire process array etching method of the present application;

FIG. 5 is a schematic diagram of an improved etching process of the present application;

FIG. 6 is a flowchart of yet another conducting wire process arrays etching method of the present application.

### DETAILED DESCRIPTION OF THE INVENTION

In order to enable the skilled in the art to better understand technical solutions in the present application, the technical solutions in the embodiments of the present application are clearly and completely described below in combination with the drawings in the embodiments of the present application. Apparently, the described embodiments are only partial embodiments rather than all embodiments of the present application. On the basis of the embodiments in the present application, all other embodiments obtained by those of ordinary skill in the art shall fall within the protection scope of the present application on the premise of not contributing innovative work.

With the development of the thin film transistor liquid crystal display apparatuses having aspects, such as an ultra-large size, high driving frequencies, high resolution ratios, and the like, when the thin film transistor liquid crystal display apparatus is manufactured, use of a high-quality conducting wire process technology is necessary. How to effectively reduce resistance of a panel conducting wire is very important, so replacing aluminum metal wires with low-resistance copper or silver metals are a hot-spot center of discussion of the present panel industry.

In an undisclosed solution of the inventor, metal containing silver or silver alloys has been used as a metal material for a gate and a source/drain. The solution actually solves the resistance problem of the panel conducting ire quite well, but a thin film transistor element using metal containing silver or a silver alloys as the gate/source/drain at least has the following defects. For example, in such a case, there is poor adhesion to a substrate or a semiconductor layer, the thin film transistor element easily reacts with chloride and sulfide when etching to reduce electrical conductivity and heat conductivity, easily coagulates in increasing resistivity when thermal tempering, and is prone to strip the gate/source/drain duo to bad adhesiveness after the gate/source/drain is forced, resulting in low yield.

In the thin film transistor of the present application, because silver or silver alloys are expensive, production cost is increased, so that the silver or silver alloys are not used, and copper with a high electrical conductivity is selected as a main material for the source/drain metal. Because copper poorly adheres to the semiconductor layer, a transition layer is added between the source/chain metal and the semiconductor layer, and the transition layer forms a multilayer metal film with the source/drain metal. The inventor uses alloys containing titanium, tantalum, nickel, chromium, tungsten, cobalt, magnesium, vanadium, or other metals as the material of the transition layer, and finally uses the molybdenum as a material of the transition layer to form the multilayer metal film, in which an upper portion is copper and a lower portion contacting the N+ semiconductor layer is molybdenum.

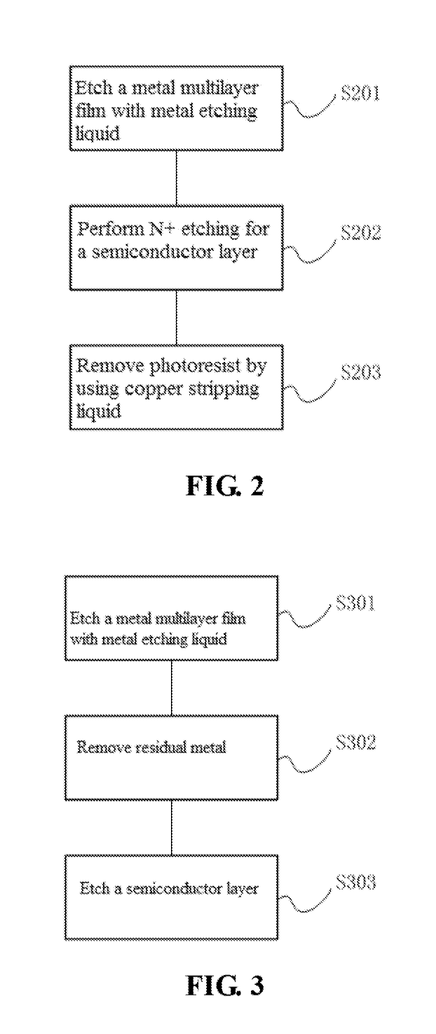

Correspondingly, FIG. 2 shows a flowchart of a process for manufacturing a thin film transistor substrate, and referring to the content shown in the flowchart, the inventor uses a manufacturing process as follows:

S101: forming a gate on a substrate;

S102: forming a gate insulation layer on the substrate to cover the gate;

S103: forming a semiconductor layer on the gate insulation layer;

S104: performing plasma ionization for the semiconductor layer to form an ohmic contact layer having a preset thickness;

S105: forming a metal layer on the gate insulation layer to cover the ohmic contact layer;

S106: patterning the metal layer and the ohmic contact layer to form a source and a drain, and to expose an area of the semiconductor layer between the source and the drain;

S107: forming a passivation layer on the source, the drain, and the exposed semiconductor layer;

S108: forming a contact hole for exposing the drain in the passivation layer; and

S109: forming a pixel electrode on the passivation layer, and connecting the pixel electrode to the drain through the contact hole.

Corresponding the etching process described below is a previous etching solution used by the inventor. The etching process mainly occurs at the step “S106: patterning the metal layer and the ohmic contact layer to form the source and the drain, and to expose the area of the semiconductor layer between the source and the drain”, the step includes the etching process, and FIG. 2 shows an etching flowchart before the improvement.

Specifically, the etching process includes the following steps:

S201: performing S/D cupric acid etching on a multilayer metal film;

S202: performing N+ etching on a semiconductor layer (N+); and

S203: removing the photoresist using copper stripping liquid.

In addition, the etching process further includes various deposition processes, yellow light exposure processes, and the like, which is not repeated herein because this portion is not an inventive point of the present application.

For the etching process, because in the process for performing the S/D cupric acid etching on multilayer metal film, the problem of residual molybdenum leads to the problem of incomplete N+ etching, and results in low product yield.

The semiconductor layer includes an N+ semiconductor layer. In the present application, the N+ semiconductor layer mainly refers to a layer above the gate insulation layer and below the source and the drain.

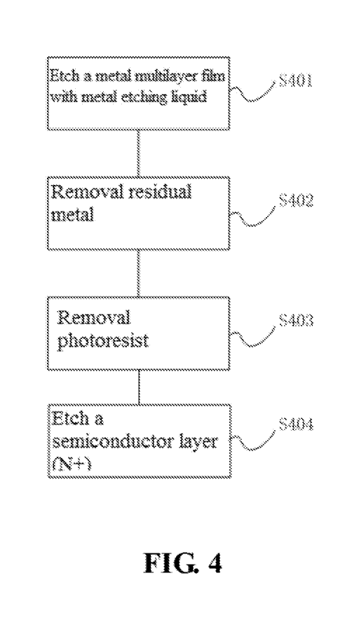

In the embodiment shown in FIG. 3, FIG. 3 is a flowchart of a conducting wire process array etching method of the present application. Referring to FIG. 3, the conducting wire process array etching method includes the steps:

S301: etching a multilayer metal film with metal etching liquid;

S302: removing residual metal; and

S303: etching a semiconductor layer (N+).

Where the semiconductor layer includes an N+ semiconductor layer. In the present application, the N+ semiconductor layer mainly refers to a layer above the gate insulation layer and below the source and the drain.

In using the multilayer metal film in the present application, when the patterns are etched, incomplete etching is easy to occur, resulting in N+ residue in subsequent etching of the semiconductor, leading to low product yield and increase in production cost. In the present application, because the residual metal is actually removed on purpose after the metal etching liquid is used to etch the multilayer metal film, the problem of the N+ residue in subsequent steps is avoided, product yield is increased, and production cost is reduced. Specifically, the multilayer metal film may be a copper/molybdenum multilayer film, an aluminum/molybdenum multilayer film, a copper/titanium multilayer film, and the like, the corresponding metal etching liquid is mainly used for etching copper or aluminum, and also is used for certain etching purposes for the molybdenum and titanium. However, the problem of slow etching of the metal on the lower portion is likely to occur, and the residual metal problem will lead to the incomplete etching of N+ in subsequent N+ etching processes. In consideration of this problem, and particularly for the problem of the residual metal at the lower portion of the multilayer metal film selected by the inventor, the specific removal of the residual metal is performed, so that when N+ etching is performed, the problem of incomplete N+ etching caused by the residual metal at the upper portion of the N+ semiconductor layer is avoided, and product yield is ensured. The etching liquid used for the N+ etching can be selected from conventional etching liquid as long as the etching liquid meets N+ etching requirements.

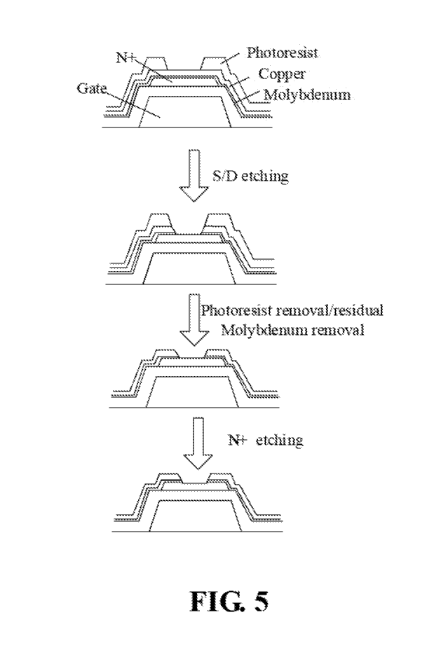

In one or more embodiments, in the embodiment shown in FIG. 4, FIG. 4 is a flowchart of another conducting wire process array etching method of the present application. Referring to FIG. 4 and in combination with FIG. 2 and FIG. 3, it can be known that:

prior to the etching of the semiconductor layer, the method further includes the step:

removing a photoresist. Of course, the step of removing the photoresist and the step of removing the residual metal can be simultaneously performed or can be successively performed, and arrangement of the steps can be exchanged.

Specifically, the process flow is as follows:

S401: etching a multilayer metal film with metal etching liquid;

S402: removing residual metal;

S403: removing a photoresist; and

S404: etching a semiconductor layer (N+).

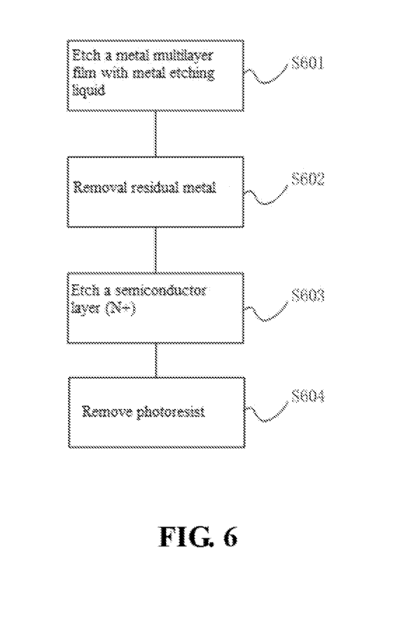

FIG. 5 is a schematic diagram of the improved etching process of the present application. As shown in FIG. 5, a main “island” structure is formed by a bottom substrate, in which a gate metal layer on the substrate and an N+ semiconductor layer above the gate metal layer. A source/drain metal layer and a photoresist layer are formed on the “island” through various deposition methods. The photoresist is provided with an inverted trapezoidal “volcanic vent” structure mainly used for etching the source/drain metal layer of an area in the “volcanic vent.” The area above the N+ semiconductor layer will be finally exposed, for example, in the present solution, the metal etching liquid is used to etch the multilayer metal film forming the source/drain metal layer, and in subsequent steps, the N+ semiconductor layer in the exposed area is slightly etched to achieve a final desirable structure.

In one or more embodiments, referring to FIG. 5 and in combination with FIG. 4 and FIG. 3. it can be known that in the present solution, step S402 and step S403 are simultaneously performed, and the residual metal is residual molybdenum.

The photoresist and the residual molybdenum are simultaneously removed using universal stripping liquid. In the present solution, the multilayer metal film includes a copper/molybdenum multilayer film or an aluminum/molybdenum multilayer film. In taking copper/molybdenum multilayer film as an example, copper is used as a main material for manufacturing a source/drain conducting wire, while molybdenum is used as a material of the transition layer. Specifically, the upper portion is copper/copper alloys, while the molybdenum/molybdenum alloys are used in the position where lower portion is in contact with the semiconductor layer alloys. In this way, the conducting wire can be attached well onto the semiconductor layer, and because copper metal has low resistance, copper can be used as the conducting wire to work. Correspondingly, when the metal etching liquid is used for etching, because the copper is at the upper layer, and the metal etching liquid has a bad effect on etching the molybdenum, when the CD bias requirement is met after the copper/aluminum etching is completed, etching of the molybdenum is not complete, thus causing the molybdenum to remain. At this moment, a universal stripping liquid is used to remove the residual molybdenum and also to remove a glass photoresist, so that when N+ etching, N+ residue can be avoided, product yield is ensured, and production cost is reduced.

In one or more embodiments, the universal stripping liquid includes a high-concentration of amine stripping liquid. A main component of the universal stripping liquid is a high-concentration of amine stripping liquid, and use of the universal stripping liquid can simultaneously complete removal o the residual molybdenum and the photoresist, thereby achieving dual purposes.

In one or more embodiments, the photoresist is removed using copper stripping liquid.

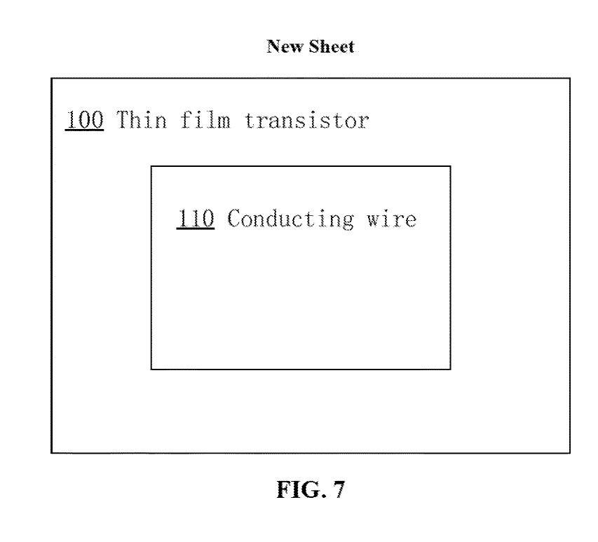

In One or embodiments, in the embodiment shown in FIG. 6, after the step of etching the semiconductor layer, the method further includes the step:

removing a photoresist using copper stripping liquid.

Specifically, the process flow is as follows:

S601: etching a multilayer metal film with metal etching liquid;

S602: removing residual metal;

S603: etching a semiconductor layer (N+); and

S604: removing the photoresist. In the present solution, compared with the embodiment shown in FIG. 5, the step of removing the residual metal and the step of removing the semiconductor layer (N+) are not integrated. That is, the photoresist and the residual molybdenum are not simultaneously removed with the universal stripping liquid, and dual purposes are not achieved, so that one more step is needed, However, the present solution has the advantages of first removing the residual metal of the multilayer metal film, so that the problem of N+ residue is avoided, and product yield is ensured. Moreover, because the photoresist is removed after the N+ etching, the situation where other portions of the multilayer metal film are carelessly etched when N+ etching or when the residual molybdenum is removed, can be avoided. The etching step is mainly used to etch patterns in the area between the source/drain and above the semiconductor layer rather than etching the entire multilayer metal film, although the photoresist and the residual molybdenum can be simultaneously removed as long as the dosage and the time are well controlled without influencing other portions. In the specific production process, the uncontrollable situation may occur, so that the etching process is performed as above. Of course, when in specific production, the step of removing the photoresist can be performed before or after the N+ etching according to the influences of the factors such as production efficiency, production quality, quality control, and the like.

In one or more embodiments, the multilayer metal film is a copper/molybdenum multilayer film.

The metal etching liquid includes copper etching liquid. The copper/molybdenum multilayer film specifically forms the source/drain conducting wire metal, where the upper portion is copper and serves as a conductor main body to ensure conductivity and low resistance, while the lower portion is provided with a molybdenum layer as a transition layer of the copper and the semiconductor layer to avoid the problem of had adhesion of copper. Of course, the upper portion of the copper may also be provided with an optional molybdenum layer. In addition, the metal etching liquid can be used as long as components of the metal etching liquid are suitable for copper etching, where the copper etching liquid can mainly include S/D cupric acid and is mainly used for etching copper or copper alloys to form patterns Meanwhile, the copper etching liquid also has an etching effect for metal on the lower layer such as the molybdenum. Of course, it should be understood that the copper etching liquid can also be a mixed acid based on hydrogen peroxide (H2O2) or a mixed acid based on phosphoric acid, which is not repeated here as it is not a main inventive point of the present application.

In one or more embodiments, the copper/molybdenum multilayer film includes a multilayer film having a copper upper layer and a lower molybdenum layer, or the multilayer film having a copper middle layer and upper and lower layers of molybdenum Because the copper has a low adhesion to the glass substrate and the insulating film, and the silicon oxide film has diffusion problems, and poor adhesion to the semiconductor layer may lead to unnecessary problems, so that the copper multilayer replaced by the multilayer film having a copper upper layer and a lower molybdenum layer, or the multilayer film having a copper middle layer and upper and lower layers of molybdenum. The multilayer film structure is mainly used at the formed source/drain conducting wire metal. Of course, because the gate is formed on the substrate when the gate includes silver, copper or silver alloys and copper alloys, the molybdenum or molybdenum alloys can also be used as a transition layer between the substrate and the gate metal or between the gate metal and the semiconductor layer so as to avoid the stripping problem caused by the low adhesion, thereby increasing product yield.

In one or more embodiments, the multilayer metal film is a copper/molybdenum multilayer film. The copper/molybdenum multilayer film includes a multilayer film having a copper upper layer and a lower molybdenum layer, or the multilayer film having a copper middle layer and upper and lower layers of molybdenum.

The photoresist is removed while the residual molybdenum is removed.

The photoresist and the residual molybdenum are removed using a high-concentration of amine stripping liquid.

In one or more embodiments, prior to the step of etching the multilayer metal film with the metal etching liquid, the method further includes the steps:

forming a gate on a substrate;

forming a gate insulation layer on the substrate including the gate;

forming a semiconductor layer on the gate insulation layer;

forming a source and a drain on the semiconductor layer; and

forming a pixel electrode connected with the drain.

The source and the drain are formed by the multilayer metal film. Because this step is independent from the inventive point of the present application, the exposure and development step are not illustrated. The multilayer metal film is optionally used with the multilayer file structure in which the upper portion is copper and the lower portion is molybdenum, and the copper can also be replaced by copper alloys, silver, or silver alloys. The molybdenum may also be replaced by molybdenum alloys, titanium, titanium alloys, and the like. When different metals are selected, a different metal etching liquid is used, but the metal etching liquid has good etching qualities mainly for main components such as copper of the conducting wire and has slightly bad qualities for etching metal such as the molybdenum. Of course, it can be almost the same. Because the molybdenum is arranged on the lower layer, incomplete etching of the molybdenum may also occur even if the metal etching liquid has almost a same effect for the copper and molybdenum. The present solution involves the manufacturing process of the gate/source/drain prior to the etching process. The process of the entire thin film transistor manufacturing portion related to the etching process is illustrated herein, but because the process of the portion or the preliminary process or later process not shown is not the main inventive point of the present application, the processes are not repeated.

The above describes optional specific embodiments of the present application in detail. It shall be appreciated that various modifications and variations can be made by those of skill in the art according to the concept of the present application without contributing the creative work. Therefore, the technical solutions obtained by those of skill in the art by means of logical analysis, reasoning, or limited experiments on the basis of the prior art in accordance with the concept of the present application are within the protection scope defined by the claims.

1. A method adapted to etching at least one conducting wire, comprising:
etching a multilayer metal film with metal etching liquid;
removing residual metal; and
etching a semiconductor layer;
prior to the etching of the semiconductor layer, the method further comprises the step of:
removing a photoresist;
prior to the step of etching the multilayer metal film with the metal etching liquid, the method further comprises the steps of:
forming a gate on a substrate;
forming a gate insulation layer on the substrate comprising the game;
forming a semiconductor layer on the gate insulation layer;
forming a source and a drain on the semiconductor layer; and
forming a pixel electrode connected to the drain;
wherein the source and the drain are formed by the multilayer metal film; and the residual metal is residual molybdenum;
removing the photoresist and the residual molybdenum simultaneously using universal stripping liquid;
removing the photoresist using copper stripping liquid, wherein the multilayer metal film is a copper/molybdenum multilayer film; the copper/molybdenum multilayer film comprises a multilayer film haying a copper upper layer and a lower molybdenum laver, or a multilayer film having a copper middle layer and upper and lower layers of molybdenum; wherein the metal etching liquid comprises copper etching liquid.

2. A conducting wire process array etching method comprising the steps:
etching a multilayer metal film with metal etching liquid;
removing residual metal; and
etching a semiconductor layer.

3. The conducting wire process array etching method according to claim 2, wherein
prior to the etching of the semiconductor layer, the method comprises the step of:
removing a photoresist.

4. The conducting wire process array etching method according to claim 3,
wherein the steps adapted to removing photoresist and the steps adapted to removing residual metal are carried out at the same time.

5. The conducting wire process array etching method according to claim 3, wherein the residual metal is residual molybdenum; and
the photoresist and the residual molybdenum are simultaneously removed using universal stripping liquid, the universal stripping liquid comprises a high-concentration of amine shipping liquid.

6. The conducting wife process array etching method according to claim 3, wherein the photoresist is removed using copper stripping liquid.

7. The conducting wire process array etching method according to claim 2, wherein the residual metal is residual molybdenum.

8. The conducting wire process array etching method according to claim 2, wherein the residual metal is removed using a high-concentration of amine stripping liquid.

9. The conducting wire process array etching method according to claim 2, wherein after the step of etching the semiconductor layer, the method further comprises the step:
removing the photoresist using copper stripping liquid.

10. The conducting wire process array etching method according to claim 2, wherein the multilayer metal film is a copper/molybdenum multilayer film; and
the metal etching liquid comprises copper etching liquid.

11. The conducting wire process array etching method according to claim 10, wherein the copper/molybdenum multilayer film comprises a multilayer film having a copper upper layer and a lower molybdenum layer or a multilayer film having a copper middle layer and upper and lower layers of molybdenum.

12. The conducting wire process array etching method according to claim 10, wherein the copper/molybdenum multilayer film comprises a multilayer film having a copper upper layer and a lower molybdenum layer, or a multilayer film having a copper middle layer and upper and lower layers of molybdenum.

13. The conducting wire process array etching method according to claim 2, wherein the multilayer metal film is a copper/molybdenum multilayer film; and the copper/molybdenum multilayer film comprises a multilayer film having a copper upper layer and the lower molybdenum layer, or a multilayer film having a copper middle layer and upper and lower layers of molybdenum; wherein While the residual molybdenum is removed, the photoresist is also removed; and
the photoresist and the residual molybdenum are removed using a high-concentration of amine stripping liquid.

14. (canceled)

15. (canceled)

16. (canceled)

17. (canceled)

18. The conducting wire process array etching method according to claim 2, wherein prior to the step of etching the multilayer metal film with the metal etching liquid, the method further comprises the steps:
forming a gate on a substrate;
forming a gate insulation layer on the substrate comprising the gate;
forming a semiconductor layer on the gate insulation layer;
forming a source and a drain on the semiconductor layer; and
forming a pixel electrode connected with the drain;
wherein the source and the drain are formed by the multilayer metal film.

19. (canceled)

20. (canceled)

21. The conducting wire process array etching method according to claim 2, wherein the multilayer metal film is the copper/molybdenum multilayer film, and the copper/molybdenum multilayer comprises a multilayer film having a copper alloy upper layer and a lower molybdenum alloy layer.

22. The conducting wire process array etching method according to daft wherein the multilayer metal film is the copper/titanium multilayer film, and the copper/titanium multilayer comprises a multilayer film having a copper or copper alloy upper layer and a lower titanium or titanium alloy layer.

23. The conducting wire process array etching method according to claim 2, wherein the multilayer metal film is the silver/titanium multilayer film and the silver/titanium multilayer comprises a multilayer film having a silver or silver alloy upper layer and a lower titanium or titanium alloy layer.

24. The conducting wire process array etching method according to claim 2, wherein the multilayer metal film is the silver/titanium multilayer film, and the silver/titanium multilayer comprises a multilayer film having a silver or silver alloy upper layer and a lower molybdenum or molybdenum alloy layer.

25. A thin film transistor, the thin transistors are fabricated by a wire process array etching method, the wire process array etching method comprises the steps of:
etching a multilayer metal film with metal etching liquid;
removing residual metal; and
etching a semiconductor layer.
